(19) United States
(12) Patent Application Publication
(10) Pub. No.: US 2008/0066683 A1
(43) Pub. Date: Mar. 20, 2008

(54) Assembly with Enhanced Thermal Uniformity and Method For Making Thereof

(75) Inventors: Kensuke Fujimura, Hyogo (JP); Akira Miyahara, Osaka (JP); Takeshi Higuchi, Kobe (JP)

Correspondence Address: MOMENTIVE PERFORMANCE MATERIALS INC.-Quartz;c/o DILWORTH & BARRESE, LLP, 333 Earle Ovington Blvd., Uniondale, NY, 11553, US

(73) Assignee: General Electric Company, Schenectady, NY (US)

(21) Appl. No.: 11/554,573

(22) Filed: Oct. 30, 2006

Related U.S. Application Data
(60) Provisional application No. 60/826,150, filed on Sep. 19, 2006.

(51) Int. Cl. C23C 16/00

(52) U.S. Cl. 118/724; 118/725; 118/728

(57) ABSTRACT

An assembly is provided for regulating the temperature of and supporting a heating target such as semiconductor substrate or a metal/ceramic mold or other industrial processes that require temperature regulations such as degassing or annealing. In one embodiment, the assembly comprises a heating target support for supporting the heating target ; a ceramic heating element for heating the heating target to a temperature of at least 300° C.; a first thermally conductive layer disposed between the substrate support and the ceramic heating layer; a second layer disposed below the ceramic heating layer. Both the first layer and the second layer in the heater assembly have an elastic modulus of less than 5 GPa, for biasing the ceramic heating layer without causing damage to the ceramic layer while still providing uniform and excellent heating to the substrate.

### CROSS REFERENCE TO RELATED APPLICATION

This application claims the benefits of U.S. patent application Ser. No. 60/826,150 filed Sep. 19, 2006, which patent application is fully incorporated herein by reference.

### FIELD OF INVENTION

The invention relates generally to an assembly for regulating the temperature of a substrate in a semiconductor-processing chamber, for regulating the temperature of a metal or ceramic mold including glass molding, for degassing, for alloying, or other industrial processes that require temperature regulations.

### BACKGROUND OF THE INVENTION

Resistive heaters have been popular means of heating the target due to the high energy efficiency and easier measurement and control. Among those resistive heaters, ceramic heaters are typically selected when higher temperatures than the conventional metal heater can survive is required. Ceramic heaters are also employed for processes that are sensitive to metal contaminations. Semiconductor processes, metal or ceramic molding, degassing, and alloying are examples of fields where ceramic heaters are typically employed. Applications in those fields typically requires the target to reach the temperatures of 600° C. or higher. Temperature control of the heating target, i.e., semiconductor wafer or mold, is critical to meet the required process performance.

Thermal regulation apparatuses that include a resistive heater may also include a separate part of a target support member in between the target and the resistive heater. Such structures are desired for example when the resistive heater needs to be protected from the harsh process environment, mechanical loads, or contamination. Such target support member is also desired when enhanced temperature uniformity on the heating target is required. In such structures, generally, there are two areas of concern relating to temperature control of the heating target. The first concern is heat transfer between the heating target and the surface of the target support, and the second is the thermal regulation of the target support from within the assembly structure. Assembled thermal devices typically have problem of thermal contact resistance. It becomes even more important issue under vacuum or low gas pressure (20 Pa or less) environment where convection heat transfer by gas is less effective. Generally, a backside gas, such as argon or helium, is used as a heat transfer medium between the substrate and the target support to compensate for such heat transfer difficulty.

The target support member may have functionality, e.g., vacuum or electrostatic chuck to hold the heating target at a position. As another example of the functionality, the target support may work as RF electrode for plasma processing.

The second concern is the thermal regulation of the target support. Thermal regulation of the target support from within the assembly is generally provided by a metallic cooling plate located within the assembly. Promoting conductive heat transfer through materials having the solid to solid contact encourages higher heat transfer rates, as thermal conduction through solid materials occurs at a higher rate in contrast to thermal transfer through air gaps or voids, including gaps induced by surface irregularities (flatness, roughness, etc.) in the mating surfaces. It is desired for improved energy efficiency, faster heating/cooling, and protection of non-heat-resistant parts in the assembly such as elastomer o-ring.

Thermal interface material (TIM) layers have been employed to maximize the solid-to-solid contact between the ceramic support and the cooling plate. U.S. Pat. No. 6,292,346 discloses the use of a metallic foil or carbon sheet having a thickness of less than 500 μm. U.S. Pat. No. 6,563,686 discloses the use of a conformal graphite interstitial layer to provide enhanced thermal conductivity. However, in order to get the best performance of out of the graphite or carbon layers, sufficient compression against the heating element and the target support member is required to minimize the air gaps or voids in the mating surfaces.

However, the method of using a single TIM layer disclosed by the patents quoted above is not readily applicable to ceramic heaters. Although ceramic heaters have a number of advantages over conventional metal heaters, ceramic parts commonly have inherent disadvantage of brittleness. It is difficult to obtain sufficient compression against the heater to maximize the performance of the TIM layer without damaging the heating element. Ineffective heat transfer caused by insufficient compression has been a common problem of the ceramic heaters. In addition, the TIM compression solutions in the prior art fail to provide uniform temperature distribution on the heating target, a requirement for semiconductor processes and lens molding processes. Repeatability and reproducibility has been another problem related to the insufficient contact to the TIM. The performance is sensitive to the actual contact area which depends on the part-by-part variation and assembly operator variation.

Therefore, there is a need for a heater assembly having improved heat transfer characteristics with minimal effects on the heating element.

### SUMMARY OF THE INVENTION

In one aspect, the invention relates to an assembly for regulating the temperature of and supporting a target in a process chamber such as a wafer processing chamber or a high temperature molding chamber, the assembly comprising a target support for supporting the wafer substrate or the mold; a ceramic heating element for heating the target to a temperature of at least 300° C.; a first thermally conductive layer disposed between the target support and the ceramic heating layer; a second layer disposed below the ceramic heating layer. The first layer and the second layer both comprise a material having an elastic modulus of less than 5 GPa, for biasing the ceramic heating layer without causing damage to the ceramic layer while still providing uniform and excellent heating to the substrate.

In one embodiment, both the first and second layers comprise the same material such as graphite. In a second embodiment, the first layer comprises a graphite sheet and the second layer comprises a ceramic felt material. In a third embodiment, the second layer has a thickness of at least 500 μm.

### BRIEF DESCRIPTION OF THE DRAWINGS

FIG. 1 is a perspective view showing one embodiment of a ceramic heater.

FIGS. 2A, 2B, and 2C are cross-sectional views of various embodiments of the ceramic heater of FIG. 1 with different layered configurations.

FIG. 3 is an exploded view of one embodiment of an embodiment of the heater assembly of the invention.

FIG. 4 is a cross-sectional view of another embodiment of the heater assembly of the invention.

FIG. 5 is a cross-sectional view of a third embodiment of the heater assembly of the invention.

### DETAILED DESCRIPTION OF THE INVENTION

As used herein, approximating language may be applied to modify any quantitative representation that may vary without resulting in a change in the basic function to which it is related. Accordingly, a value modified by a term or terms, such as “about” and “substantially,” may not to be limited to the precise value specified, in some cases.

As used herein, the term “target” or “substrate” refers to the semiconductor wafer or the mold being supported/heated by the heating assembly of the invention. Also as used herein, the “treating apparatus” may be used interchangeably with “heater,” “heater assembly,” “heating apparatus,” or “processing apparatus,” referring to an assembly containing at least one heating element and/or a cooling equipment to regulate the temperature of the substrate supported thereon.

As used herein, the term “circuit” may be used interchangeably with “electrode,” and the term “heating element” may be used interchangeably with “resistor,” “heating resistor,” or “heater.” The term “circuit” may be used in either the single or plural form, denoting that at least one unit is present.

As used herein, the term “sheet” may be used interchangeably with “layer.”

The assembly such as a heating apparatus provides effective heat conduction between a heating element and a target, e.g., heating wafer substrates heating molds, or heating other forms of specimen container, wherein the heating targets are heated up to a temperature of at least 300° C. The apparatus provides a relatively uniform temperature distribution to the target even for heating element with an imperfect, e.g., uneven, contact surface. Embodiments of the assembly are illustrated as follows, by way of a description of the materials being employed, the assembly of the components, the manufacturing process thereof and also with references to the figures.

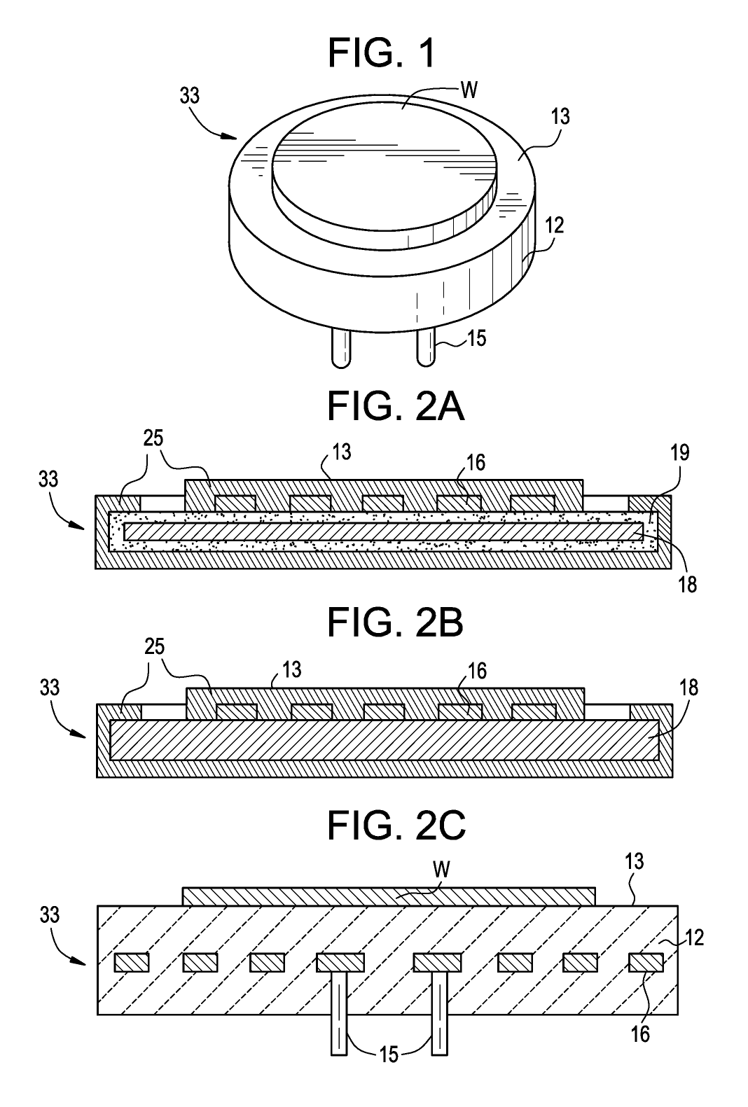

General Embodiments of the Ceramic Heating Element: In one embodiment, the assembly includes a ceramic heater 33 as illustrated in FIG. 1. Ceramic heater 33 comprises a disk-shaped dense ceramic substrate 12 having a heating resistor 16 buried therein (not shown), whose top surface 13 serves as a supporting surface for a heating target, i.e., a wafer, a mold, or other specimen container S. Electric terminals 15 for supplying electricity to the heating resistor can be attached at the center of the bottom surface of the ceramic substrate 12, or in one embodiment, at the sides of the ceramic substrate.

In one embodiment as illustrated in FIG. 2A, the ceramic base substrate comprises a disk or substrate 18 containing an electrically conductive material, having an overcoat layer 19 that is electrically insulating, and optionally a tie-layer (not shown) to help enhance the adhesion between the layer 19 and the base substrate 18. Examples of electrically conductive material include graphite; refractory metals such as W and Mo, transition metals, rare earth metals and alloys; oxides and carbides of hafnium, zirconium, and cerium, and mixtures thereof. With respect to the overcoat layer 19, the layer comprises at least one of an oxide, nitride, carbide, carbonitride or oxynitride of elements selected from a group consisting of B, Al, Si, Ga, Y, refractory hard metals, transition metals; oxide, oxynitride of aluminum; and combinations thereof. With respect to the optional tie-layer, the layer comprises at least one of: a nitride, carbide, carbonitride, boride, oxide, oxynitride of elements selected from Al, Si, refractory metals including Ta, W, Mo, transition metals including titanium, chromium, iron; and mixtures thereof. Examples include TiC, TaC, SiC, MoC, and mixtures thereof.

In one embodiment as illustrated in FIG. 2B, the base substrate 18 comprises an electrically insulating material including sintered ceramics, e.g., selected from the group of oxides, nitrides, carbides, carbonitrides or oxynitrides of elements selected from a group consisting of B, Al, Si, Ga, Y, high thermal stability zirconium phosphates, having the NZP structure of NaZr₂ (PO₄)₃, refractory hard metals, transition metals; oxide, oxynitride of aluminum; and combinations thereof, having high wear resistance and high heat resistance properties. In one embodiment, the base substrate 18 comprises AlN of >99.7% purity and a sintering agent selected from Y₂O₃, Er₂O₃, and combinations thereof.

In one embodiment as illustrated in FIG. 2C, an electrode 16 having an optimized circuit design is “buried” in the ceramic substrate 12. The heating element 16 comprises a material selected from the group of pyrolytic graphite, tungsten, molybdenum, rhenium and platinum or alloys thereof, carbides and nitrides of metals belonging to Groups IVa, Va and VIa of the Periodic Table; carbides or oxides of hafnium, zirconium, and cerium, and combinations thereof. In one embodiment, the heating element 16 comprises a material having a coefficient of thermal expansion (CTE) that closely matches the CTE of the substrate (or its coating layer).

In another embodiment as illustrated in FIGS. 2A-2B, the heating element 33 comprises a film electrode 16 having a thickness ranging from 5-1000 μm, which is formed on the electrically insulating base substrate 18 (of FIG. 2B) or the coating layer 19 (of FIG. 2A) by processes known in the art including screen-printing, spin coating, plasma spray, spray pyrolysis, reactive spray deposition, sol-gel, combustion torch, electric arc, ion plating, ion implantation, sputtering deposition, laser ablation, evaporation, electroplating, and laser surface alloying. In one embodiment, the film electrode 16 comprises a metal having a high melting point, e.g., tungsten, molybdenum, rhenium and platinum or alloys thereof In another embodiment, the film electrode 16 comprises at least one of carbides or oxides of hafnium, zirconium, cerium, and mixtures thereof.

In the heater assembly of the invention, one or more electrodes can be employed. Depending on the application, the electrode may function as a resistive heating element, a plasma-generating electrode, an electrostatic chuck electrode, or an electron-beam electrode.

In one embodiment of the invention as illustrated in FIGS. 2A and 2B, the ceramic heater 33 is further coated with an etch resistant protective coating film 25, comprising at least one of: a nitride, carbide, carbonitride or oxynitride of elements selected from a group consisting of B, Al, Si, Ga, Y, refractory hard metals, transition metals, and combinations thereof, a zirconium phosphate having an NZP structure of NaZr₂(PO₄)₃; a glass-ceramic composition containing at least one element selected from the group consisting of elements of the group 2a, group 3a and group 4a; a BaO—Al₂O₃—B₂O₃—SiO₂ glass; and a mixture of SiO₂ and a plasma-resistant material comprising an oxide or fluoride of Y, Sc, La, Ce, Gd, Eu, Dy and yttrium-aluminum-garnet (YAG). In one embodiment, the coating film comprises a material having a CTE ranging from 2.0×10⁻⁶/K to, 10×10⁻⁶/K in a temperature range of 25 to 1000° C. In another embodiment, the layer 25 comprises a high thermal stability zirconium phosphates, having the NZP structure of NaZr₂(PO₄)₃, as well as to related isostructural phosphates and silicophosphates having a similar crystal structure. In a third embodiment, the layer 25 contains a glass-ceramic composition containing at least one element selected from the group consisting of elements of the group 2a, group 3a and group 4a of the periodic table of element. Examples of suitable glass-ceramic compositions include lanthanum aluminosilicate (LAS), magnesium aluminosilicate (MAS), calcium aluminosilicate (CAS), and yttrium aluminosilicate (YAS). The thickness of the protective coating layer 25 varies depending upon the application and the process used, e.g., CVD, ion plating, ETP, etc, varying from 1 μm to a few hundred μm, depending on the application.

General Embodiments of the Assembly: In one embodiment, the temperature regulating equipment, e.g., the heating element 33 is wholly or partially enclosed with a heater case and the heat transfer mode between the heating element and the heater case is dominated by conduction. In another embodiment, the heater case is transparent, allowing direct radiation heating through the heater case to the heating target S in addition to the conduction. In yet another embodiment, the heater case is opaque. In one embodiment, processing of the heating target S is generally carried out in a partial vacuum, and wherein a backside gas is used to enhance heat transfer between the substrate S and the ceramic heater 10.

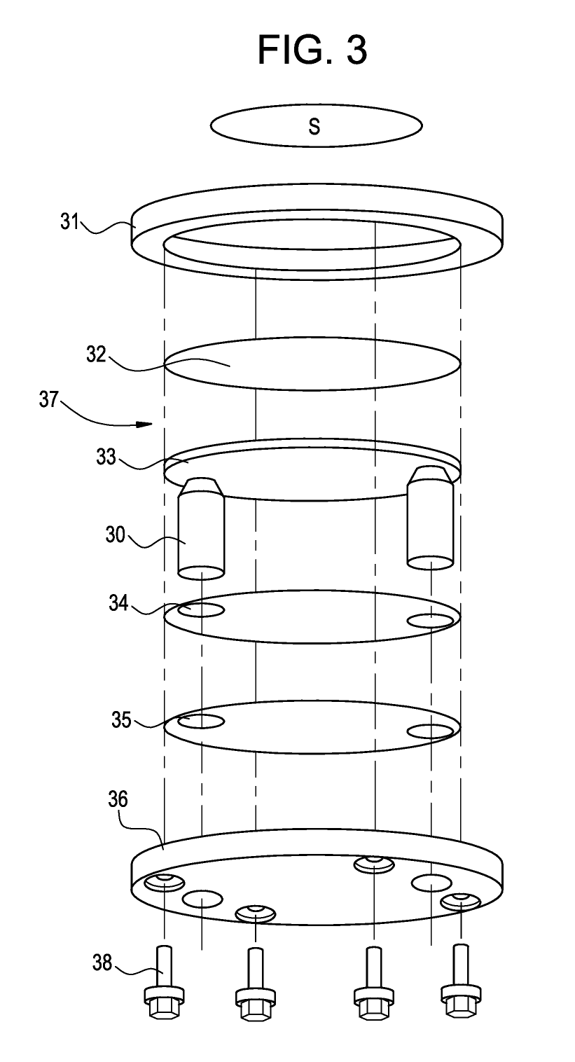

FIG. 3 depicts an exploded view of an embodiment of a heater assembly. Starting from top to bottom, the assembly with a heater case 37 comprises a target support member 31, a first thermally conductive sheet 32, a heating element 33, a second sheet 34, an optional thermal insulator layer 35, and a platform 36. A support member 31 is provided to support the heating target S. In one embodiment, the support member 31 and the platform 36 are joined together by mechanical fasteners or other fastening means 38, thus forming a heater case 37 that fully encloses the rest of the parts. Examples of mechanical fasteners include rods, screws, bolts and the like. In one embodiment, the support member 31 is joined with the platform 36 via the use of ceramic bonds, adhesives, and the like. In one embodiment, a spring or other elastic means may be used as the fastening means 38.

In one embodiment, both the first and second sheets bias (press) against the heating element 33 and support member 31 in operation, for a close contact between the sheets and the heating element at a bias force against the heating element 33 in the range of 0.05 to 30 psi. In one embodiment, the bias force against the heating element 33 (or a temperature regulating equipment such as a cooling equipment) is in the range of 0.10 to 20 psi.

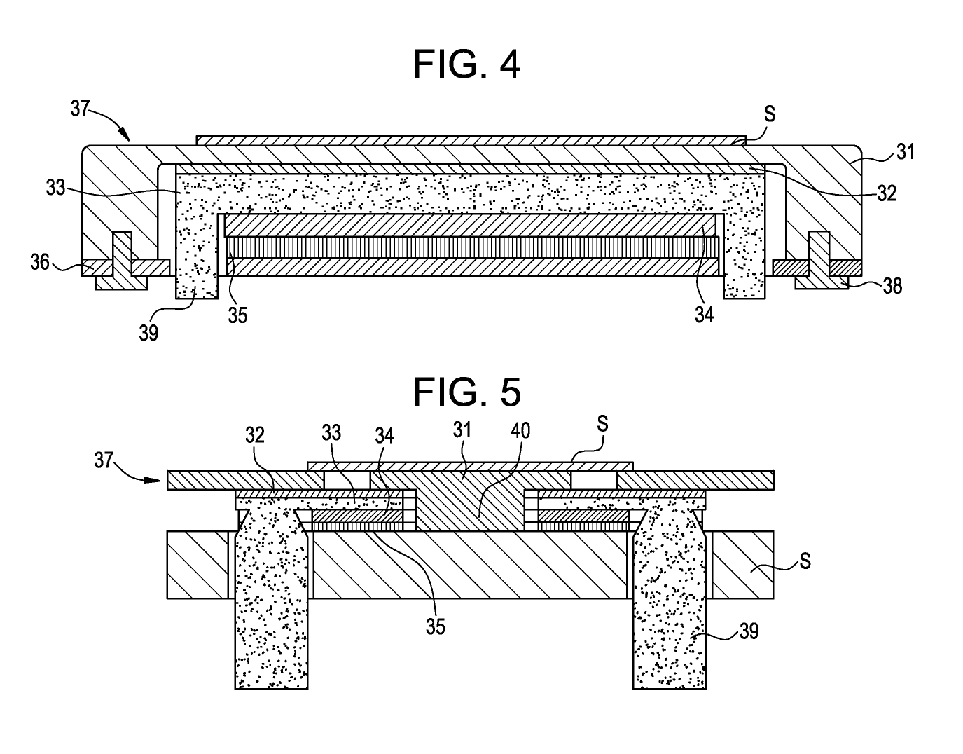

In other embodiments as illustrated in FIG. 5, the heater case 37 partially covers the inner assembly. In the Figure, electrical power is supplied through the power supply portion 39 of the heating element 33. In FIGS. 4 and 5, power supply means are monolithically extended from the heating element 33. Yet in another embodiment (not shown), the power supply means 39 comprise flexible wires connected to the heating element 33. The power supply means in one embodiment are configured such that they do not restrict the vertical displacement of the heating element 33, allowing the heating element 33 to freely move along with thermal expansion of the carbon sheets or other parts of the heater assembly. In one embodiment as illustrated in FIGS. 4 and 5, the first thermally conductive sheet 32 on the heating target side S is thinner than the second sheet 34, thus allowing more effective heat transfer toward the heating target S by differentiating thermal resistance.

In one embodiment, the assembly further comprises an optional layer of thermal insulator 35 disposed under the second sheet 34 in order to add more thermal resistance. In one embodiment (not shown), a thermal insulation layer is disposed between the second sheet 34 and the heating element 33. In yet another embodiment, an additional thermal insulation layer 35 is disposed under the second thermally conductive sheet 34.

In one embodiment of FIG. 5, power supply means comprise graphite posts with a tapped hole, extending from the heater 33, which is designed to accept electrically conductive threaded rods. The electrically conductive threaded rods may be further connected with flexible wires (not shown). In one embodiment, embedded pyrolytic graphite (PG) electrode is used as the heating element in the heater 33. In another embodiment to protect the PBN ceramic heater from the process load, a support boss facing on the platform 40 is extruded from the target support member 31.

In operation, the substrate S is thermally regulated by passing heat (i.e., thermal energy) from the heating element 33 to the first thermally conductive sheet 32, the target support member 31, to the substrate S. The target support member 31 and the platform 36 comprise the same or different material, selected from the group of copper, stainless steel, high speed steel, tungsten, molybdenum, Kovar® or alloys thereof. If the two components comprise different materials, they preferably have matching coefficient of thermal expansion (CTE), i.e., with one material having a CTE ranging from 0.75 to 1.25 the CTE of the second material. Alternatively, ceramics or sintered hard alloys may be selected. Examples include but are not limited to aluminum nitride, silicon nitride, silicon carbide, tungsten carbide, graphite, etc.

The thermal insulator layer 35 is typically fabricated from a low thermal conductivity material. Examples include but are not limited to pyrolytic boron nitride, silicon nitride, alumina, zirconia, quartz glass, etc. The layer has a thickness ranging from 50 μm to 1 cm. In one embodiment, the insulator layer 35 has a thickness of at least 100 μm. In a second embodiment, a thickness of less than 5 mm. In a third embodiment, the thermal insulator layer has a thickness ranging from 100-2000 μm.

Both the first thermally conductive sheet 32 and the second sheet 34 are characterized as being ductile, i.e., comprising a material with elastic property/flexibility to give the sheet a cushioning/springy characteristic to deform elastically and compress the temperature regulating equipment, e.g., heating element 33 against the case 32 with minimal or no damage to the heating element. Exemplary materials include but are not limited to carbon sheet, ceramic fabric, ceramic felt, ceramic foam, graphite foam, and the like with excellent ductility. In one embodiment, the first and second sheets comprise the same or different materials, with the material of construction having an elongation property of at least 5%. In a second embodiment, the material has an elastic modulus of less than 10 GPa. In a third embodiment, the sheets comprise a material having an elastic modulus of less than 5 GPa. In a fourth embodiment, the sheets have an elastic modulus of less than 1 GPa. In a fifth embodiment, the sheets comprise a material with compressibility of at least 20%. In a sixth embodiment, the sheets comprise a material with compressibility of at least 40%.

In addition to the ductility property, the first sheet 32 is further characterized with an excellent thermal conductivity property. Thermally conductive property is not a requirement for the second sheet. However, in one embodiment, the second sheet 34 comprises a material which is both thermally conductive and ductile such as graphite. In one embodiment, the second sheet 34 comprises a material which is thermally insulative and ductile such as ceramic felt or foam.

In one embodiment, the first sheet 32 comprises a ductile material such as carbon having a thermal conductivity of about 20 W/mK in a plane parallel to the heating element. In a second embodiment, at least one of the first and second sheets comprises a layer of graphite foam having a thermal conductivity of at least 100 W/mK. In a third embodiment, each of the first and second sheets comprises a plurality of layers of different materials, e.g., inter-layers of carbon sheet and graphite foam. In one embodiment, the first and second sheets comprise a graphite sheet commercially available as Grafoil®, having compressibility property (ASTM F-36) of 43% and elastic modulus of 1380 MPa. In another embodiment, the first sheet is a Grafoil® sheet, and the second sheet comprises a ceramic fabric having elastic modulus of less than 2 GPa and a porosity of less than 20 vol. %.

In one embodiment, the first thermally conductive sheet 32 and the second sheet 34 each has a thickness ranging from 50 μm to 10 mm. In a second embodiment, each sheet has a thickness ranging from 100 μm to 5 mm. In a third embodiment, each sheet has a thickness ranging from 100 μm-2 mm with the second sheet 34 having a thickness of 1.5 to 4 times the thickness of the first thermally conductive sheet 32. In a fourth embodiment, the first sheet 32 has a thickness of 200 μm and the second sheet 32 has a thickness of 600 μm.

As the heating element 33 is sandwiched in between two sheets 32 and 34 with each sheet having excellent cushioning characteristics, the sheets fill up the space between the ceramic heater 33 and the heater case caused by the thermal expansion at elevated temperatures. Additionally, because the sheets on both sides of the heating element 33 provide even support against the entire surface area of both sides of the heater 33, any bow on the heating element 33 is set straight without applying excess force on partial spots of the heating element 33 which is especially important function when the heating element 33 is constructed out of brittle ceramic materials. Moreover, the anisotropic thermal conductivity of the first sheet 32 which comprises materials such as carbon, graphite, and the like, the first sheet 32 spreads the heat to the planar direction while allowing the heat to be transferred through to the heating target S.

As the thermal conductivity of hexagonal carbon and/or graphite is high in the direction parallel to layers but low in the direction through thickness, this anisotropic property further improves the temperature uniformity on the target support member 31, and thus on heating target S. Additionally, as heat generated in the heating element is conducted through the first thermally conductive sheet 32 and the second sheet 34, more heat can be directed to transfer towards the first sheet 32 by controlling the thermal resistance difference between the first and second sheets, e.g., having a much thicker second sheet 34 or using a thermally insulating material such as ceramic felt for the second sheet 34.

In one embodiment of the invention with the use of thermally conductive materials for both sheets 32 and 34, the thermal performance of the heater can be predicted with great accuracy. Thermal contact resistance between parts in heater assembly is typically difficult to predict due to low repeatability and reproducibility caused by the product-by-product variation, the assembly operator variation, the surface and flatness condition, and etc. Such unpredictability has been a problem when a heating device is designed. Experiments are often required to find the thermal contact resistance, which is often costly and time consuming. However, with the use of ductile material which has the same thermal conductivity and elasticity for both sheets 32 and 34, the heating element 33 is in between sheets of the same thermally conductive materials, the contact condition on both sides of the heater is always even. As long as a predetermined power is generated in the heating element, it is eventually transferred, thus allowing excellent thermal performance modeling for heating the substrate to temperatures in the range of 300-700° C. while minimizing the performance variation caused by the thermal contact resistance variation.

The embodiments illustrated herein are for an assembly with at least a heating element for heating a heating target. However, embodiments with cooling equipment are within the scope with the invention with cooling equipment being assembled in the assembly in place of the heating element described herein. In one embodiment, a cooling plate is used in place of the heating element, for regulating the substrate temperature to −80° C. In a second embodiment, a cooling plate is used in addition to the heating element to regulate the target temperature in the range of −80° C. to 600° C. The use of the first thermally conductive sheet 32 and the second sheet 34 in conjunction with a cooling equipment in an assembly such as a semiconductor wafer-holder enables the temperature of a substrate to be regulated uniformly.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims. All citations referred herein are expressly incorporated herein by reference.

1. An assembly for regulating the temperature of and supporting a heating target in a process chamber, the assembly comprising:
a target support member having a top surface and a bottom surface, the top surface adapted to support the heating target;
a temperature regulating equipment for regulating the substrate temperature, the temperature regulating equipment having a top surface and a bottom surface;
a first layer disposed between the target support and the temperature regulating equipment, the first layer is biased against the top surface of the temperature regulating equipment, the first layer comprises a material having a thermal conductivity of at least 20 W/mK in a plane parallel to the temperature regulating equipment and an elastic modulus of less than 1GPa;
a second layer disposed below the temperature regulating equipment, the second layer is biased against the bottom surface of the temperature regulating equipment, and the second layer comprises a material having an elastic modulus of less than 1 GPa.

2. The assembly of claim 1, wherein the temperature regulating equipment comprises a ceramic heater and a cooling plate for regulating the temperature of the substrate in a range of −80° C. to 600° C.

3. The assembly of claim 1, wherein the temperature regulating equipment is a ceramic heater for heating the heating target to a temperature of at least 300° C.

4. The assembly of claim 1, wherein either the first layer or the second layer comprises a material having an elongation property of at least 5%.

5. The assembly of claim 1, wherein either the first layer or the second layer comprises a material having a compressibility of at least 20%.

6. The assembly of claim 1, wherein the first layer and the second layer each has a thickness of 50 μm-10 μm.

7. The assembly of claim 1, wherein the second layer has a thickness of at least 500 μm and the first layer has a thickness of at least 100 μm.

8. The assembly of claim 1, wherein the second sheet has a thickness of 1.5 to 4 times a thickness of the first sheet.

9. The assembly of claim 1, wherein both the first and second layers are biased against the ceramic heating element at a force of less than 30 psi.

10. The assembly of claim 1, wherein both the first and second layers are biased against the ceramic heating element at a force of less than 10 psi.

11. The assembly of claim 1, wherein both the first and second layers are biased against the ceramic heating element at a force of less than 2 psi.

12. The assembly of claim 1, wherein the first layer comprises at least a graphite layer.

13. The assembly of claim 1, wherein the second layer comprises a material selected from: graphite sheet, ceramic felt, ceramic foam, carbon sheet, ceramic fabric, and graphite foam.

14. The assembly of claim 1, wherein the temperature regulating equipment is a ceramic heater for heating the heating target to a temperature of at least 300° C., and the assembly further comprises:
a thermally insulating layer disposed below the second layer; and
a platform sealingly coupled to the target support member, forming a case housing the first and second layers, the ceramic heater, and the thermally insulating layer.

15. The heater assembly of claim 1, wherein both the first layer and the second layer each comprises a plurality of graphite sheets.

16. The heater assembly of claim 1, wherein the first sheet is a graphite sheet.

17. The assembly of claim 1, for regulating the temperature of and supporting at least a semiconductor wafer in a wafer-processing chamber.

18. The assembly of claim 1, wherein the heating target is at least a glass mold.

19. A heater assembly for heating and supporting a heating target in a process chamber, the assembly comprising:
a target support member having a top surface and a bottom surface, the top surface adapted to support the heating target;
a ceramic heating element for heating the heating target to a temperature of at least 300° C., the ceramic heating element having a top surface and a bottom surface;
a first layer disposed between the target support member and the ceramic heating element, the first layer is biased against the top surface of the ceramic heating element, the first layer has a thermal conductivity of at least 20 W/mK in a plane parallel to the ceramic heating element and an elastic modulus of less than 1 GPa;
a second layer disposed below the ceramic heating element, the second layer is biased against the bottom surface of the ceramic heating element, the second layer comprising a material having an elastic modulus of less than 1 GPa,
wherein the ceramic heating element comprises an over-coating layer comprising one of: a nitride, carbide, carbonitride, oxynitride of elements selected from a group consisting of B, Al, Si, Ga, Y, refractory hard metals, transition metals, and combinations thereof; a zirconium phosphate having an NZP structure of NaZr₂(PO₄)₃; a glass-ceramic composition containing at least one element selected from the group consisting of elements of the group 2a, group 3a and group 4a; a BaO—Al₂O₃—B₂O₃—SiO₂ glass; and a mixture of SiO₂ and a plasma-resistant material comprising an oxide or fluoride of Y, Sc, La, Ce, Gd, Eu, Dy and yttrium-aluminum-garnet (YAG).

20. A heater assembly for heating and supporting a heating target in a process chamber, the assembly comprising:
a target support member having a top surface and a bottom surface, the top surface adapted to support the heating target, the target support member comprises a transparent or opaque quartz material;
a ceramic heating element for heating the heating target to a temperature of at least 300° C., the ceramic heating element having a top surface and a bottom surface;
a first layer disposed between the target support member and the ceramic heating element, the first layer is biased against the top surface of the ceramic heating element, the first layer comprises a material having a thermal conductivity of at least 20 W/mK in a plane parallel to the ceramic heating element and compressibility of at least 20%;
a second layer disposed below the ceramic heating element, the second layer is biased against the bottom surface of the ceramic heating element, the second layer comprising a material having an elongation property of at least 5%.
